(19) United States
(12) Patent Application Publication
(10) Pub. No.: US 2006/0145172 A1
(43) Pub. Date: Jul. 6, 2006

(54) Light emitting diode with a quasi-omnidirectional reflector

(76) Inventors: Jung-Chieh Su, Hsinchu (TW); Cheng-Wei Chu, Hsinchu (TW)

Correspondence Address: RABIN & Berdo, PC, 1101 14TH STREET, NW, SUITE 500, WASHINGTON, DC, 20005, US

(21) Appl. No.: 11/150,103

(22) Filed: Jun. 13, 2005

(30) Foreign Application Priority Data
Dec. 30, 2004 (TW) 93141534

(51) Int. Cl. H01L 33/00

(52) U.S. Cl. 257/98; 257/100; 257/99

(57) ABSTRACT

A light emitting diode with a quasi-omnidirectional reflector comprises a luminescent gel which is coated surrounding a UV light LED chip and a quasi-omnidirectional reflector which is disposed above the luminescent gel. The quasi-omnidirectional reflector is a wild angle cut-off filter which is made by a cooperation of a method for an optical film coating and a property of a total reflection. According to the property of the optical film coating, a light with an incident angle smaller than a critical angle can be reflected, such that a light form the LED chip is confined in the luminescent gel, which makes the luminescent material is excited as much as possible for improving the conversion efficiency of the light. When this LED chip co-works with different colors of the luminescent gels, different colors of lights are excited and produced.

### BACKGROUND

1. Field of Invention

The invention relates to a light emitting diode (LED) which applies to a luminescence device, and in particular to a light emitting diode which has a quasi-omnidirectional reflector.

2. Related Art

So called “White Light” usually means a light mixing multiple colors of lights. A white light that human can see includes at least two mixed wavelengths of the color lights. For example, a blue light combines with a yellow light producing a two wavelength white light; and a blue light, a green light and a red light mix together producing a three wavelength white light.

White light LED (light emitting diode) has two major types according to the filler inside: One is organic LED and the other is inorganic LED. At present, there are three major white light sources by semiconductors: first, using a blue, a red and a green light LED chips to compose a white light luminescence module, which has advantages of high light emitting efficiency and high color rendering, and disadvantages of high cost, complex control circuit and mixing difficulty due to the different properties of three LED chips; second, using a UV light LED to excite a transparent shell that uniformly mixes blue, green, and red colors of luminescent materials, which produces a three wavelength white light after excitation, having advantages of high color rendering and disadvantages of low light emitting efficiency; third, a method provided by a Japan Company NICHIA, using a blue light LED to excite a yellow luminescent material to produce white light, which is the mainstream in the present market.

A structure diagram of the inorganic LED developed by the Japan Company NICHIA is shown in FIG. 1. A yellow luminescent material 20 is filled surrounding a blue light LED 10 which has a wavelength of 400˜530 nm. A light produced by this blue light LED 10 is used to excite the yellow luminescent material 20 for producing a yellow light, simultaneously, part of the blue light emits out and mixes with the yellow light to form a two wavelength white light.

However, because most of the light spectrum produced by this LED that combines the blue light LED 10 and the yellow luminescent material 20 are the blue lights, the color temperature is partial to high and the color of the light source is not very easy to control. Therefore, the possibility for interacting the blue light and the yellow luminescent material 20 must be increased to reduce the intensity of the blue light or to increase the intensity of the yellow light.

In order to improve the foregoing mentioned technology, a LED disclosed in U.S. Pat. No. 5,962,971 uses a UV filter as a package for the light emitting surface of a LED luminescent material layer 40, shown in FIG. 2. This method not only improves the light emitting uniformity of the luminescent material layer 40, but also absorbs the UV light from the LED chip and prevents it from hurting the human eyes. However, it causes a loss of the UV light, which reduces the light emitting efficiency of the LED. In addition, a LED disclosed in U.S. Pat. No. 5,813,753 coats a short wave pass filter on the light emitting surface of the UV light/blue light LED to improve the reflection amounts of a visible light (fluorescent light) of the light emitting surface of the LED, and the emitting amounts of the UV light/blue light of the LED. On the other hand, a long wave pass filter is used as a package at the light emitting surface of the front LED to improve the transmission ratio of the visible light.

A LED disclosed in U.S. Pat. No. 6,833,565 uses an omnidirectional reflector to form a resonance structure, which confines a UV light in the luminescent material layer to improve the light efficiency of the LED. A function of this omnidirectional reflector is to improve the reflecting ability for a specific wavelength of light which has an incident angle ranging from 0 to 90 degrees.

There are two method of manufacturing the foregoing mentioned omnidirectional reflector. One of them is using a process for one dimension photonic crystal to design and produce it. The other method is using a periodical film to stack and form, for example, using at least two types of materials to alternately and periodical stack to form an interference optical film reflection mirror.

However, although a structure made by using the periodical film to form an omnidirectional reflector helps improving the reflection ability for the UV light, it doesn't include any process for the visible light by the periodical stacking.

### SUMMARY

According the reasons above, one objective of the invention is to provide a light emitting diode (LED) having a quasi-omnidirectional reflector, which uses a method of optical film coating to manufacture a wild angle cut-off filter on the luminescent material layer. By this wild angle cut-off filter and the cooperation of it with the optical total reflection, a UV light omnidirectional reflection effect can be obtained.

The feature of the invention is the wild angle cut-off filter which is only for total reflecting a light with a specific wavelength (For example, a 360-400 nm UV light from a UV light LED), and is not for reflecting a visible light source such as a fluorescent light. Therefore a light with a UV light wavelength is confined in the luminescent gel, which allows the UV light to excite the luminescent material as much as possible, which improves the conversion efficiency of a white light. The visible light produced by the excitation of the luminescent material layer may still penetrate the wild angle cut-off filter, thus this invention can increase the penetrating ability of the visible light and practically improve the lighting efficiency of the LED.

In order to achieve the above objective, a light emitting diode with a quasi-omnidirectional reflector comprises: a substrate, at least one LED chips, a luminescent gel and a wild angle cut-off filter. The LED chip, a UV light LED chip; is disposed on the substrate and emits a light from its light emitting surface. The luminescent gel is composed of a mixture of a luminescent material and an epoxy, and is coated surrounding the UV light LED chip. When a UV light from the UV light LED chip penetrates through the luminescent gel, the luminescent material is excited and produces a second visible light, which is a fluorescent light.

The wild angle cut-off filter is made by a method of optical film coating and is disposed at a side of the luminescent gel where corresponds to an emitting surface of the LED chip. Because this wild angle cut-off filter is made by this method, it can be designed before proceeds an optical film coating on another substrate according to the desirable optical reflection, where only reflects a specific wavelength of a UV light LED chip and doesn't reflect the visible light.

If an incident angle of a light emitting to the wild angle cut-off filter is smaller than a specific angle, the wild angle cut-off filter will total reflect the light due to the design of optical film coating on it. On the other hand, if an incident angle of a light emitting to the wild angle cut-off filter is larger than the specific angle, the light will also be totally reflected and confined in the luminescent gel to excite the luminescent material as much as possible because of the differences between the refraction index of the luminescent gel and that of the air for improving the conversion efficiency of the white light.

Because the wild angle cut-off filter doesn't reflect a visible light from the luminescent gel, a visible light such as a fluorescent light can penetrate through the wild angle cut-off filter and emit. Further after designing some visible light wavelengths of specific fluorescent lights, the lighting amounts penetrating through the wild angle cut-off filter may be controlled for achieving a purpose of controlling the color temperature and the brightness of a light from the LED.

Of course, the invention is not limited to a white light LED, a UV light LED may co-work with different colors of the luminescent materials to emit different colors of lights according to the desire of a user, which may apply to more applications.

### BRIEF DESCRIPTION OF THE DRAWINGS

FIG. 1 is a diagram showing a conventional inorganic LED.

FIG. 2 is a diagram showing a conventional LED structure which uses a UV light filter as a package at the emitting surface of the LED luminescent material layer.

FIG. 3 is a diagram showing the first embodiment of the invention.

FIG. 4 is a diagram showing the second embodiment of the invention.

FIG. 5 is a diagram showing the third embodiment of the invention.

FIG. 6 is a diagram showing the fourth embodiment of the invention.

FIG. 7 is a diagram showing the fifth embodiment of the invention.

FIGS. 8 and 9 show the spectrums of the wild angle cut-off filter with different colors of LEDs.

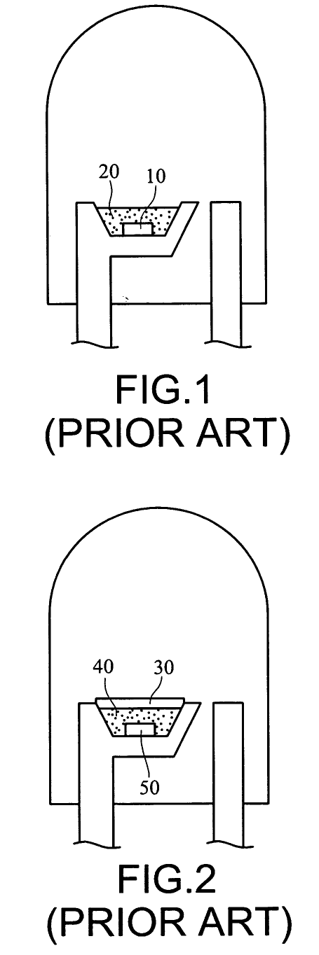

### DETAILED DESCRIPTION

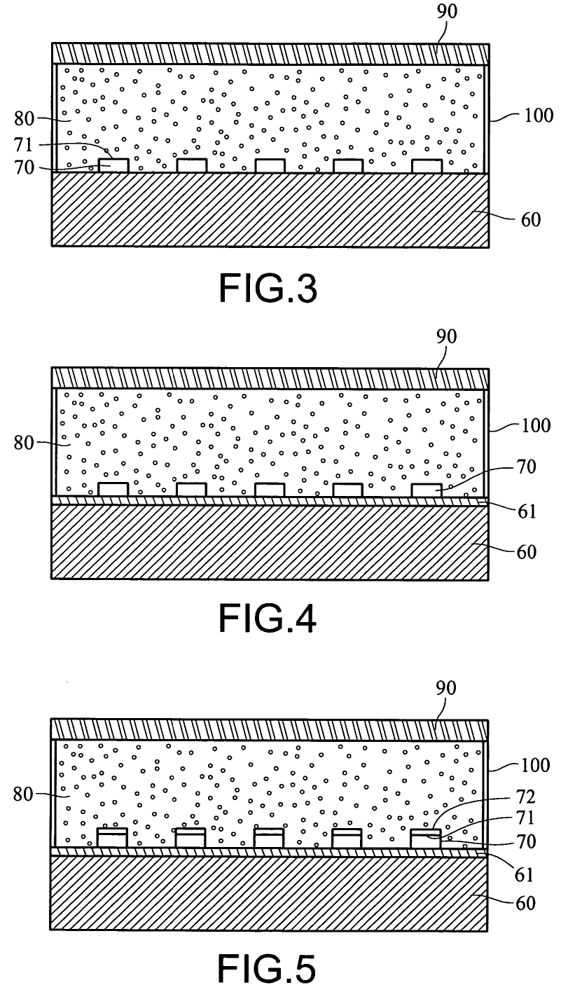

Please refer to FIG. 3, it is a diagram of the first embodiment of a LED with a quasi-omnidirectional reflector according to the invention. This LED includes: a substrate 60; at least one LED chips 70, a luminescent gel 80, a wild angle cut-off filter 90 and a side reflector 100.

The LED chip 70 is disposed on a substrate 60 which has an ability for providing a circuit thereon and for driving the LED chip 70 to emit a light by an external current. A light emits from an emitting surface of the LED chip 70 for providing a light source to excite the luminescent gel 80.

In the drawing, this LED includes five LED chips. However, practically a user can dispose one or more LED chips therein to provide the desirable brightness. When more than one LED chips 70 are disposed therein, they can be arranged in matrix.

The LED chip 70 can be a UV light LED chip. The LED chip 70 can be disposed on the substrate by forming a circuit on the substrate first and then connecting the LED chip 70 to the circuit.

Surrounding of the LED chip 70 is coated with a luminescent gel 80 for providing a fluorescent light. This luminescent gel 80 is consisted of a luminescent material and an epoxy. When a light emitting form the LED chip 70 penetrating through the luminescent gel 80, the luminescent material is excited and produces a fluorescent light.

A visible light spectrum of the luminescent material used in the LED is designed according to the wavelength of a light from the LED chip 70. When a different LED chip 70 is used, a luminescent material used must corresponds to the wavelength of the light to produce a fluorescent light.

The wild angle cut-off filter 90 is made by a method of an optical film coating, and is disposed at a side of the luminescent gel 80 which corresponds to the emitting surface 71 of the LED chip 70. This optical coating film may toward the air or the luminescent gel 80.

Because this wild angle cut-off filter is made by a method of an optical film coating, a coating material and its thickness can be firstly determined before forming the wild angle cut-off filter 90 on the substrate according to the desirable light reflection, such that only a wavelength of a specific LED chip 70 will be reflected and a visible light such as a fluorescent light will not be reflected. Besides, this wild angle cut-off filter 90 can be designed for improving the reflection ratio for a light emitting angle of a specific LED and for the different polarizations of an electric field.

This wild angle cut-off filter 90 is made by a method of an optical film coating, such as a sputtering process, an E-gun process and a chemical vapor deposition process, which continuously deposit at least one high refractive index material and at least one low refractive index material on a substrate, such that the wild angle cut-off filter 90 has an ability to totally reflect a UV light with a specific wavelength, and to penetrate through a visible light such as a fluorescent light for emitting.

This high refractive index material can be consisted of one or more compounds selected from a group consisted of a TiO₂, a Ta₂O₅, an Nb₂O₅, a CeO₂, and a ZnS for the thin film depositing. This low refractive index material can be consisted of either or both of a SiO₂ and an MgF₂ for the thin film depositing.

If an incident angle for a light emitting to the wild angle cut-off filter 90 is smaller than a specific angle range, the wild angle cut-off filter 90 will total reflect the light due to the design of an optical film coating on it. On the other hand, if an incident angle for a light emitting to the wild angle cut-off filter 90 is larger than the specific angle range, the light will also be totally reflected and confined in the luminescent gel to excite the luminescent material as much as possible because of the differences between the refractive index of the luminescent gel and that of the air for improving the conversion efficiency of the white light. This specific angle is also called a critical angle of the UV light.

The side reflector 100 is disposed at the periphery of the luminescent gel 80 for reflecting a light.

When a UV light from the light LED chip 70 penetrates through the luminescent gel 80, the luminescent material in it is excited and produces a second visible light, which is a fluorescent light.

However, because the wild angle cut-off filter 90 and the side reflector 100 surrounding the luminescent gel 80 will reflect a specific wavelength of a light, the light from the LED chip 70 will be confined in a space between the wild angle cut-off filter 90 and the side reflector 100. By the multiple and repeatable reflection of the light between the wild angle cut-off filter 90 and the side reflector 100, the luminescent material is excited as much as possible, which exhausts the energy of the light from the LED chip at most, such that the conversion efficiency of the white light can be improved and more white lights are produced.

The other side of the wild angle cut-off filter where corresponds to the luminescent gel 80 is the light emission position of the LED. Therefore a diffractive optical element (DOE), a dome lens, a micro lens, a long wave pass filter, a visible light pass filter or a anti-reflection coating film can be disposed thereon for increasing the brightness of a visible light from the LED.

In this embodiment, a UV light LED chip is used as the LED chip 70. A user can use it to co-work with different colors of luminescent gels 80 to excite and produce different colors of lights, such as a red light, a yellow light, a green light or a white light. Besides, using a blue light LED chip to co-work with a yellow light luminescent gel, a green light luminescent gel or a red light luminescent gel 80 can also produce a white light, a green light, a red light or other colors of lights respectively.

The second embodiment of the invention, as shown in FIG. 4, is similar to the first embodiment. The difference is that there is a reflection layer 61 at one side of the substrate 60, where corresponds to the wild angle cut-off filter 90. This reflection layer 61 makes the entire LED form a resonance structure inside, which lets the UV light multiple reflect between the wild angle cut-off filter 90 and the reflection layer 61, where the energy of the UV light is exhausted and the luminescent material can be excited as much as possible to improve the conversion efficiency of the white light. This reflection layer 61 can also be another wild angle cut-off filter.

Please refer to the FIG. 5, showing the third embodiment of the invention. The structure of this embodiment is similar with that of the second embodiment except that a short wave pass filter 72 is disposed at the light emission surface 71 of the LED chip 70 for increasing the light emitting amounts of the LED chip 70, and for reflecting the visible light excited from the luminescent material.

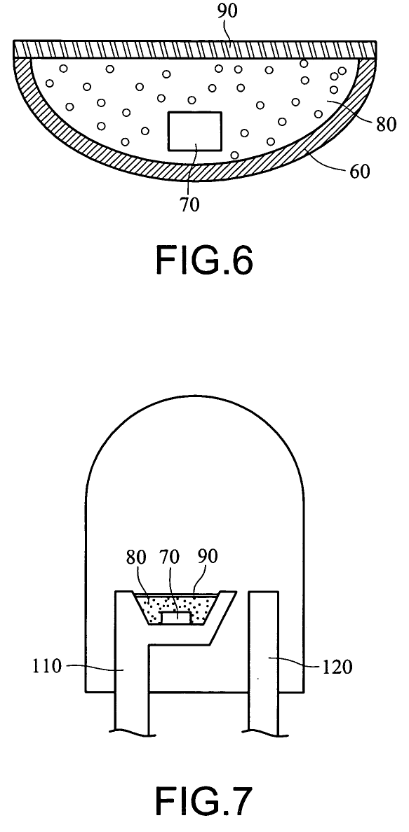

Please refer to the FIG. 6, showing the fourth embodiment of the invention. The structure of this embodiment is similar with that of the second embodiment except that the substrate 60 in the second embodiment is a plate type and the substrate 60 in this embodiment is a bowl type. The difference between these two embodiments is only on the change of the substrate appearance. Both substrates have the abilities to reflect lights. A user can choose an appropriate substrate according to his desire. Please refer to FIG. 7, showing the fifth embodiment of the invention. Firstly, a UV light LED chip 70 is fixed in a metal bowl 110 with a frame. Two pins 120 of the frame are the independent metal electrodes for applying electricity. The surrounding of the LED chip 70 is coated with a luminescent gel 80 and a wild angle cut-off filter 90 is disposed on the luminescent gel 80 by a method of an optical film coating. This method of making the wild angle cut-off filter 90 can refer to the description mentioned in the first embodiment.

By applying a current through the metal electrodes of the frame, the LED chip is driven to emit, and when the emitting light passes through the luminescent gel 80, the luminescent material is excited to produce a fluorescent light. Similarly, if an incident angle for a light emitting to the wild angle cut-off filter is smaller than the critical angle of the UV light, the wild angle cut-off filter will totally reflect the light due to the design of an optical film coating on it. On the other hand, if an incident angle for a light emitting to the wild angle cut-off filter is larger than the critical angle of the UV light, the light will also be totally reflected and confined in the luminescent gel 80. The wild angle cut-off filter 90 confines the light in the luminescent gel 80 to make the light multiple and repeatable reflect in the luminescent gel 80 for improving the conversion efficiency of the white light. By controlling the reflection ratio of the wild angle cut-off filter to the visible light, a color temperature of a light from the LED can be controlled.

Similarly, in this embodiment, a UV light LED chip is used as the LED chip 70. A user can use it to co-work with different colors of luminescent gels 80 to excite and produce different colors of lights, such as a red light, a yellow light, a green light or a white light. Besides, using a blue light LED chip to co-work with a yellow light luminescent gel, a green light luminescent gel or a red light luminescent gel 80 can also produce a white light, a green light, a red light or other colors of lights respectively.

A UV light LED and a blue light LED are used respectively in the structure of the second embodiment for two sets of experiments according to the invention. A light spectrum above the wild angle cut-off filter 90 is measured for showing the reflection effect of the wild angle cut-off filter to a UV light or a blue light, and for showing the transmission effect of the wild angle cut-off filter to a visible light.

This LED uses a 382 nm UV light LED to perform the excitation and co-works it with a red/green/blue luminescent material which is able to be excited by the above UV light, and uses a luminescent gel 80 composing of a polymer gel which is able to penetrate a UV light.

Because a light from the LED chip 70 penetrating from the luminescent gel 80 goes through the wild angle cut-off filter 90 and then goes into the air, if the refractive index of the luminescent gel is 1.48, and the incident angle of the light is larger than 42.5 degree, the light will be totally reflected.

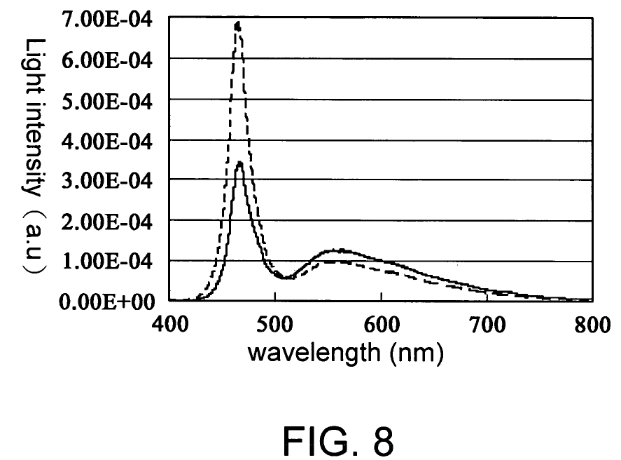

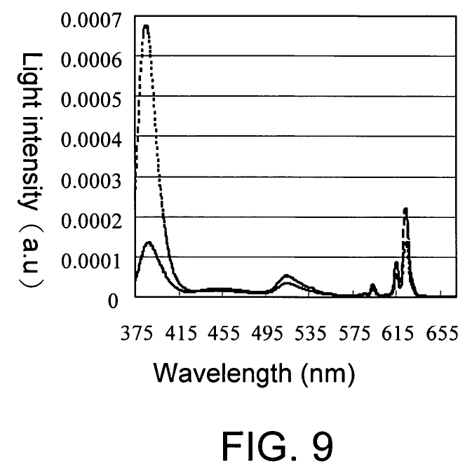

Please refer to FIG. 8, comparing to the conventional white light LED, a LED with a quasi-omnidirectional reflector which is consisted of a blue light LED chip 70 and a yellow light luminescent gel 80 has higher light emitting efficiency for a white light. It is obvious that the blue light reflects twice in the LED where reduces the intensity of the blue light and increases the intensity of the yellow light. On the other hand, please refer to FIG. 9; a LED with a quasi-omnidirectional reflector, which is consisted of a UV light LED chip 70 and a yellow light luminescent gel 80, has higher light emitting efficiency for a white light.

Although the invention has been described with reference to specific embodiments, this description is not meant to be construed in a limiting sense. Various modifications of the disclosed embodiments, as well as alternative embodiments, will be apparent to persons skilled in the art. It is, therefore, intended that the appended claims will cover all modifications that fall within the true scope of the invention.

What is claimed is:

1. A light emitting diode (LED) with a quasi-omnidirectional reflector, comprising:
a substrate, which has an ability for manufacturing a circuit;
at least one LED chips, which are disposed on the substrate and emits a light from a emitting surface of the LED chip;
a luminescent gel, which is composed of a mixture of a luminescent material and an epoxy, and is coated surrounding the LED chip, wherein when the light from the LED chip penetrates through the luminescent gel, exciting the luminescent material to produce a fluorescent light; and
a wild angle cut-off filter, which is made by a method of an optical film coating and is disposed at a side of the luminescent gel, which corresponds to the emitting surface of the LED chip, wherein when an incident angle for the light from the LED chip is larger than a specific angle range, the light will be totally reflected and confined in the luminescent gel to produce multiple and repeatable reflection due to the differences between the refractive index of the luminescent gel and that of an air for improving a conversion efficiency of a white light.

2. The light emitting diode (LED) of claim 1, wherein the LED chip is a UV light LED chip, which co-works with different colors of the luminescent gels to excite and produce different colors of the lights.

3. The light emitting diode (LED) of claim 1, wherein the LED chip is a blue light LED and the luminescent gel is a yellow light luminescent gel, producing the white light.

4. The light emitting diode (LED) of claim 1, wherein the LED chip is a blue light LED and the luminescent gel is a red light luminescent gel, producing a red light.

5. The light emitting diode (LED) of claim 1, wherein the LED chip is a blue light LED and the luminescent gel is a green light luminescent gel, producing a green light.

6. The light emitting diode (LED) of claim 1, wherein the specific angle is a critical angle of a UV light.

7. The light emitting diode (LED) of claim 1, wherein when the incident angle for the light emitting to the wild angle cut-off filter is smaller than the specific angle range, the light will be totally reflected according to a design of the optical film coating for the wild angle cut-off filter.

8. The light emitting diode (LED) of claim 1, wherein a visible light emitting spectrum of the luminescent material cooperates with a light emitting wavelength of the LED chip.

9. The light emitting diode (LED) of claim 1, wherein the substrate is a bowl type structure which has an ability to reflect the light.

10. The light emitting diode (LED) of claim 1, wherein the substrate is a plate type structure.

11. The light emitting diode (LED) of claim 1, further comprising a light reflection layer at one side of the substrate which mounts the LED chip to cooperate the wild angle cut-off filter to form a resonance structure producing multiple reflections for the light.

12. The light emitting diode (LED) of claim 1, wherein the light reflection layer is another wild angle cut-off filter.

13. The light emitting diode (LED) of claim 1, wherein the LED chip is a UV light LED chip.

14. The light emitting diode (LED) of claim 1, wherein the LED chips are arranged in matrix.

15. The light emitting diode (LED) of claim 1, wherein the emitting surface of the LED chip further comprises a short wave pass filter for increasing a light emitting amounts of the LED chip.

16. The light emitting diode (LED) of claim 1, wherein the wild angle cut-off filter reflects a light with a wavelength of the light from the LED chip.

17. The light emitting diode (LED) of claim 1, wherein the wild angle cut-off filter penetrates the fluorescent light.

18. The light emitting diode (LED) of claim 1, wherein the wild angle cut-off filter is made by using at least one high refractive index material and at least one low refractive index material to proceed the method of the optical film coating.

19. The light emitting diode (LED) of claim 18, wherein the high refractive index material is selected from one group consisted of a TiO₂, a Ta₂O₅, an Nb₂O₅, a CeO₂, and a ZnS.

20. The light emitting diode (LED) of claim 18, wherein the low refractive index material is selected from one group consisted of a SiO₂ and an MgF₂.

21. The light emitting diode (LED) of claim 1, wherein the wild angle cut-off filter is made by a method selected from one group consisted of a sputtering, an E-gun, and a chemical vapor deposition.

22. The light emitting diode (LED) of claim 1, further comprising a diffraction optical element which is disposed at another side of the wild angle cut-off filter which corresponds to the luminescent gel.

23. The light emitting diode (LED) of claim 1, further comprising a dome lens which is disposed at another side of the wild angle cut-off filter which corresponds to the luminescent gel.

24. The light emitting diode (LED) of claim 1, further comprising a micro lens which is disposed at another side of the wild angle cut-off filter which corresponds to the luminescent gel.

25. The light emitting diode (LED) of claim 1, further comprising a visible light pass filter which is disposed at another side of the wild angle cut-off filter which corresponds to the luminescent gel.

26. The light emitting diode (LED) of claim 1, further comprising an anti-reflection coating film which is disposed at another side of the wild angle cut-off filter which corresponds to the luminescent gel.

27. A light emitting diode (LED) with a quasi-omnidirectional reflector, where a LED chip is disposed in a metal bowl with a frame that has two independent metal electrodes for passing through a current to drive the LED chip for emitting a light, wherein a luminescent gel consisted of a luminescent material and an epoxy is coated surrounding the LED chip, when the light from the LED chip penetrating through the luminescent gel, the luminescent material is excited to emit a fluorescent light, wherein the light emitting diode with the quasi-omnidirectional reflector is characterized by:
a wild angle cut-off filter, which is made by a method of an optical film coating and is disposed at a surface of the luminescent gel, wherein when an incident angle for the light is larger than a specific angle range, the light will be totally reflected and confined in the luminescent gel to produce multiple and repeatable reflection due to the differences between the refractive index of the luminescent gel and that of an air for improving a conversion efficiency of a white light.

28. The light emitting diode (LED) of claim 27, wherein the LED chip is a UV light LED chip, which co-works with different colors of the luminescent gels to excite and produce different colors of the lights.

29. The light emitting diode (LED) of claim 27, wherein the specific angle is a critical angle of the UV light.

30. The light emitting diode (LED) of claim 27, wherein the LED chip is a blue light LED and the luminescent gel is a yellow light luminescent gel, producing the white light.

31. The light emitting diode (LED) of claim 27, wherein the LED chip is a blue light LED and the luminescent gel is a red light luminescent gel, producing a red light.

32. The light emitting diode (LED) of claim 27, wherein the LED chip is a blue light LED and the luminescent gel is a green light luminescent gel, producing a green light.

33. The light emitting diode (LED) of claim 27, wherein when the incident angle for the light emitting to the wild angle cut-off filter is smaller than the specific angle range, the light will be totally reflected according to a design of the optical film coating for the wild angle cut-off filter.

34. The light emitting diode (LED) of claim 27, wherein a visible light emitting spectrum of the luminescent material cooperates with a light emitting wavelength of the LED chip.

35. The light emitting diode (LED) of claim 27, wherein the wild angle cut-off filter is made by using at least one high refractive index material and at least one low refractive index material to proceed the method of the optical film coating.

36. The light emitting diode (LED) of claim 35, wherein the high refractive index material is selected from one group consisted of a TiO₂, a Ta₂O₅, an Nb₂O₅, a CeO₂, and a ZnS.

37. The light emitting diode (LED) of claim 35, wherein the low refractive index material is selected from one group consisted of a SiO₂ and an MgF₂.

38. The light emitting diode (LED) of claim 27, wherein the wild angle cut-off filter is made by a method selected from one group consisted of a sputtering, an E-gun, and a chemical vapor deposition.
